(19) United States
(12) Patent Application Publication
(10) Pub. No.: US 2012/0255921 A1
(43) Pub. Date: Oct. 11, 2012

(54) Racking Systems

(76) Inventor: David Franklin-Lees, Denham Green (GB)

(21) Appl. No.: 13/501,722

(22) PCT Filed: Oct. 11, 2010
(86) PCT No.: PCT/GB2010/001899

§ 371 Date: Jun. 27, 2012

(30) Foreign Application Priority Data
Oct. 14, 2009 (GB) 0918017.5

(51) Int. Cl. H05K 7/14; H05K 7/18

(52) U.S. Cl. 211/26; 248/309.1

(57) ABSTRACT

The present invention is for improvements in racking systems, and in particular to a racking system which can be constructed to accommodate a variety of different sized items of equipment. The racking system includes a plurality of parallel vertical support members, each provided with a series of slots spaced apart along at least a section of the length of the support member, a plurality of support rails for receiving supporting guide elements attached to an item of equipment, and at least one pair of mounting members for attachment one on each side of an item of equipment. Each mounting member comprises an individually activatable locking element such that, when the locking element is in an unlocked position, the mounting member is slidable into and out of a slot, and when the locking element is in a locked position the mounting member is restrained from movement within the slot.

The present invention relates to improvements in racking systems, and in particular to a racking system which can be constructed to accommodate a variety of different sized items of equipment.

In many fields, such as in broadcasting, telecommunications, entertainment and security, it is a common requirement to create a stack of equipment, such as audio equipment, display screens or television monitors. Often, for example in outside broadcasting, it is also necessary to be able to create temporary stacks of equipment.

Such a stack was relatively easy to achieve with bulky cathode ray tube (CRT) monitors. The dimensions of these, and many other items of rack mountable equipment, have been standardised so that they can be mounted in 19 inch (480 mm) racks, which is a standardised frame designed for mounting multiple items of equipment. A rack unit (U) is a unit of measure which describes the height of equipment intended for mounting in a 19 inch rack. A 1U piece of equipment is of a width which can be mounted across a 19 inch width rack and having a standardised height of 1.75 inches (44.45 mm); a 3U piece of equipment has the same width as a 1U piece of equipment but has a height of 3×1.75 inches; a half rack 2U piece of equipment has a height of 2×1.75 inches and will occupy half the width of a 19 inch rack.

However, as a result of the recent use of plasma and LCD technology, many modern monitors and screens are now considerably larger and flatter than previously and their dimensions preclude the possibility of directly stacking them on top of each other unaided. It is also impractical to mount these newer monitors in traditional 19 inch racks (either on shelves in the racks or attached to mounting panels affixed to the racks) as the type of equipment that can be adapted to fit a traditional 19 inch rack is limited. Other disadvantages with the traditional racks include the time taken to assemble and disassemble them, as well as the space taken up by them, particularly as they cannot be ‘flat-packed’.

It is therefore an object of the invention to provide a flexible racking system which can accommodate a variety of different types and sizes of equipment, including both standard and non-standard sized units. Another object is to provide a system which facilitates the quick change of individual items of mounted equipment in the case of failure, upgrade, or reconstruction. A further object is to provide a system which can be quickly and easily assembled and disassembled for temporary usage.

According to the invention there is therefore provided a racking system comprising a plurality of parallel vertical support members, each provided with a series of slots spaced apart along at least a section of the length of the support member, a plurality of support rails for receiving supporting guide elements attached to an item of equipment, at least one pair of mounting members for attachment one on each side of an item of equipment, each mounting member comprising an individually activatable locking element such that, when the locking element is in an unlocked position, the mounting member is slidable into and out of a slot, and when the locking element is in a locked position the mounting member is restrained from movement within the slot.

The racking system of the present invention thus enables the rapid construction of a stack of equipment, including both standard 19 inch and non-standard items, with dedicated fixings to securely lock the equipment into position.

The racking system can also be ‘flat-packed’ for economic transportation.

The invention also provides a racking system comprising at least one pair of parallel horizontal support members, each comprising a slot at one end of the member and a guide rail at the other end for receiving and supporting a guide element attached to an item of equipment, a plurality of mounting members for attachment to an item of equipment, each mounting member comprising an individually activable locking element such that, when the locking element is in an unlocked position, the mounting member is slidable into and out of a slot, and when the locking element is in a locked position the mounting member is restrained from movement within the slot.

Preferred embodiments of the invention will now be described, by way of example only, with reference to the accompanying drawings in which:

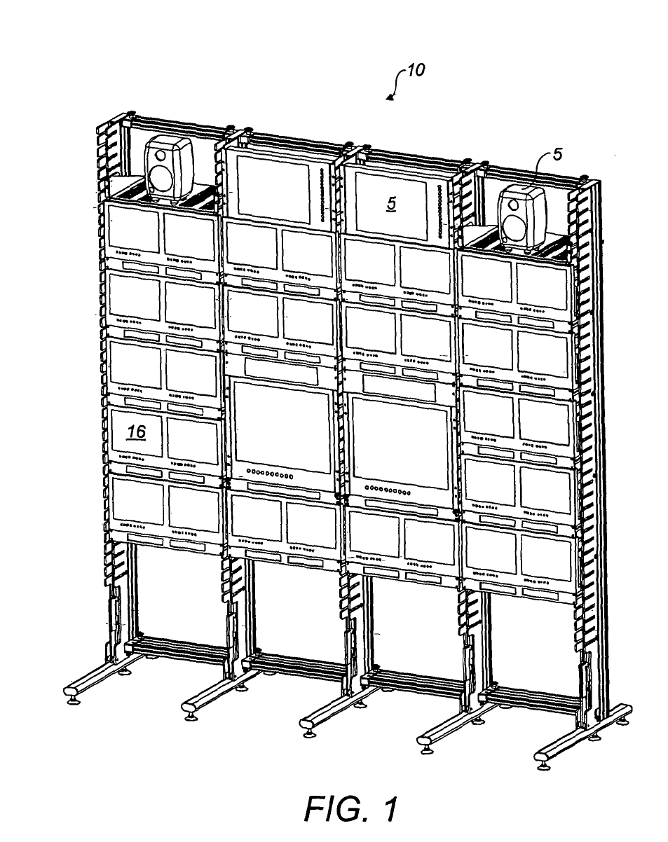

FIG. 1 is a pictorial view of a stack of audio visual equipment constructed using a racking system of the present invention;

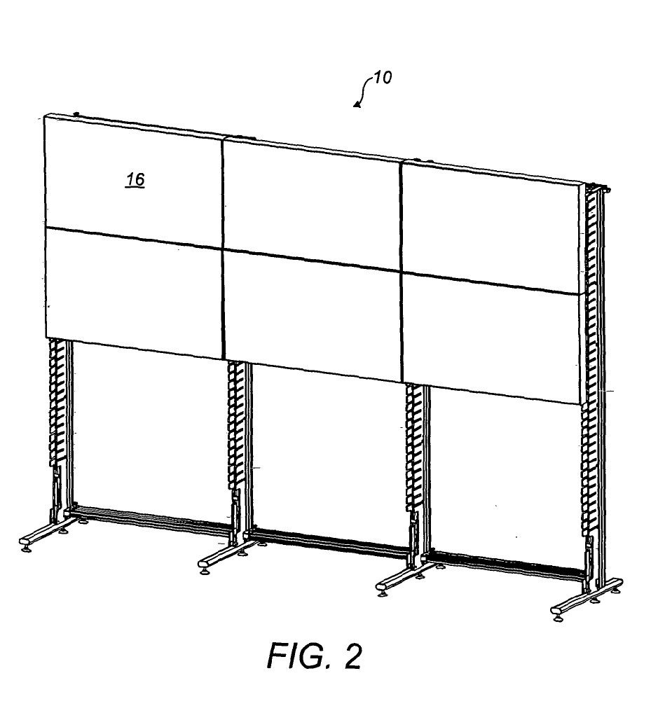

FIG. 2 is a pictorial view of the racking system of FIG. 1 on which different sized audio visual equipment from that illustrated in FIG. 1 has been mounted;

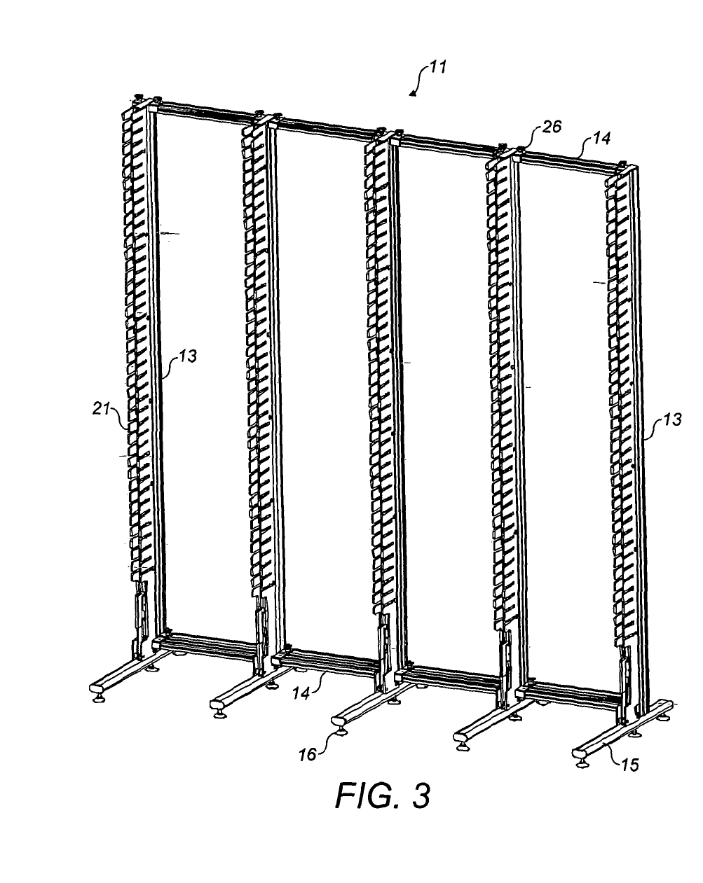

FIG. 3 is a pictorial view of a support structure of the racking system of FIG. 1;

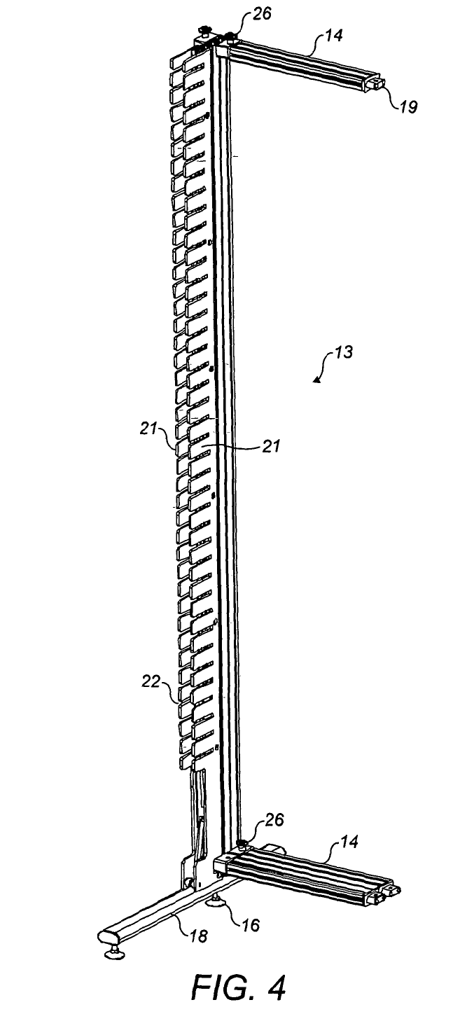

FIG. 4 is a pictorial view of a support member used to construct the support structure of FIG. 3;

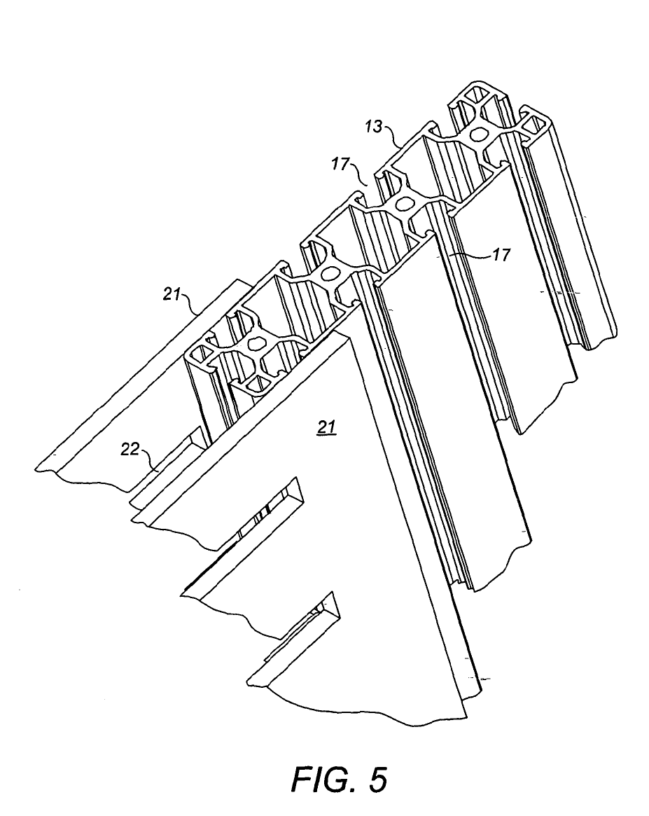

FIG. 5 is a horizontal cross-section through the support member of FIG. 4;

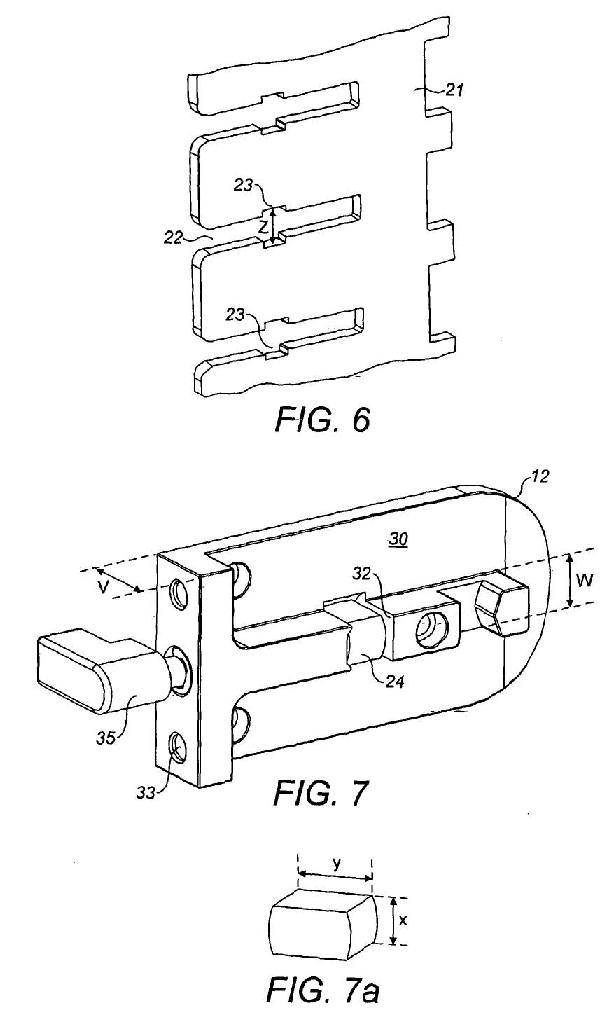

FIG. 6 is a pictorial view of an enlarged section of the slotted panel of the support member of FIG. 4;

FIG. 7 is a pictorial view of a mounting member of the racking system of FIG. 7;

FIG. 7a is a pictorial view of a locking element of the mounting member of FIG. 7;

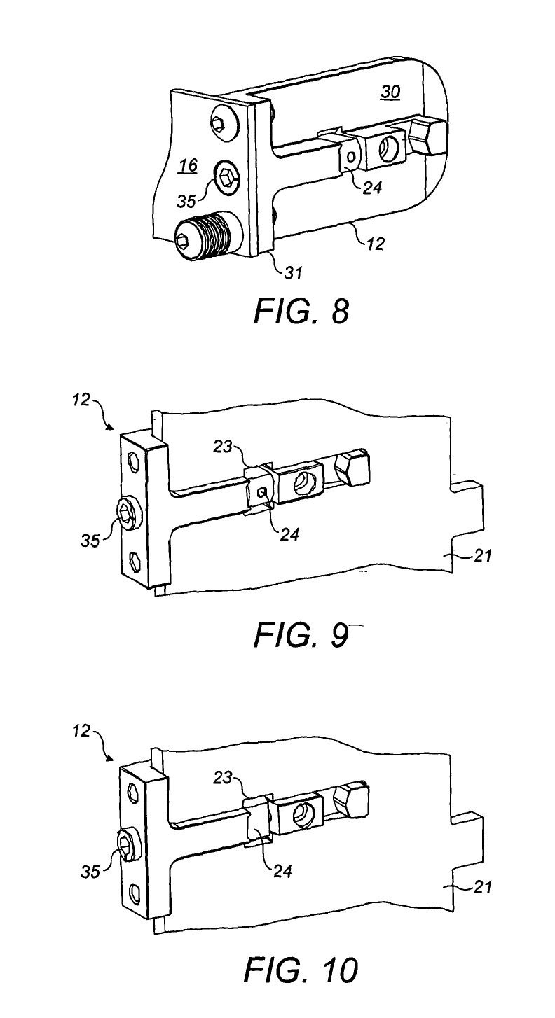

FIG. 8 is a pictorial view of the mounting member of FIG. 7 attached to an item of equipment;

FIGS. 9 and 10 are pictorial views of the mounting member of FIG. 7 inserted into a slot in the slotted panel of FIG. 6;

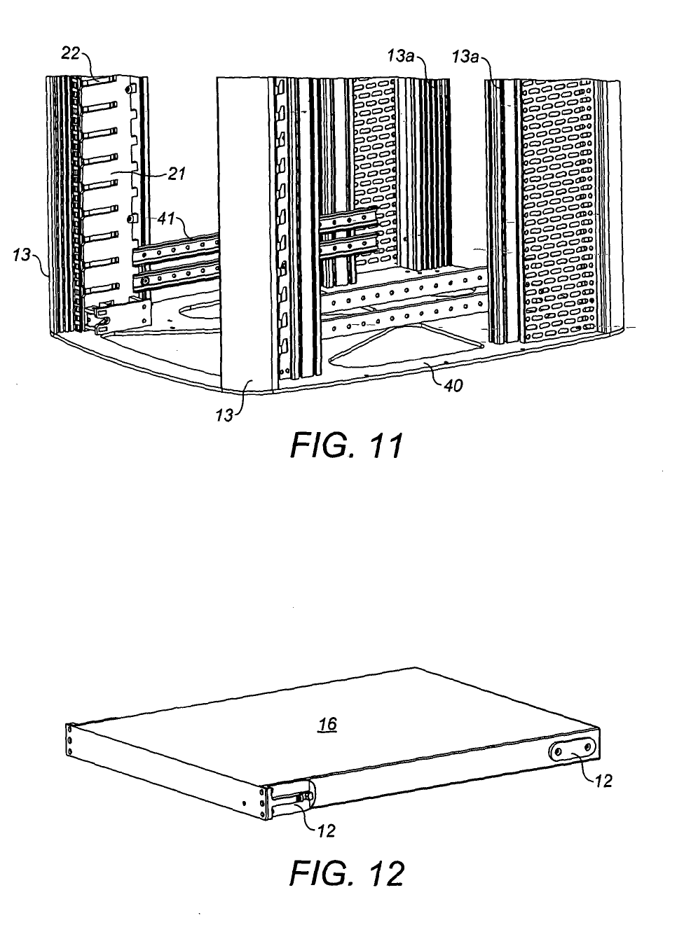

FIG. 11 is a pictorial view of the support structure of an alternative embodiment of the racking system of the present invention, including rear support members;

FIG. 12 is a pictorial view of an item of equipment to which is attached a mounting member and a guide element;

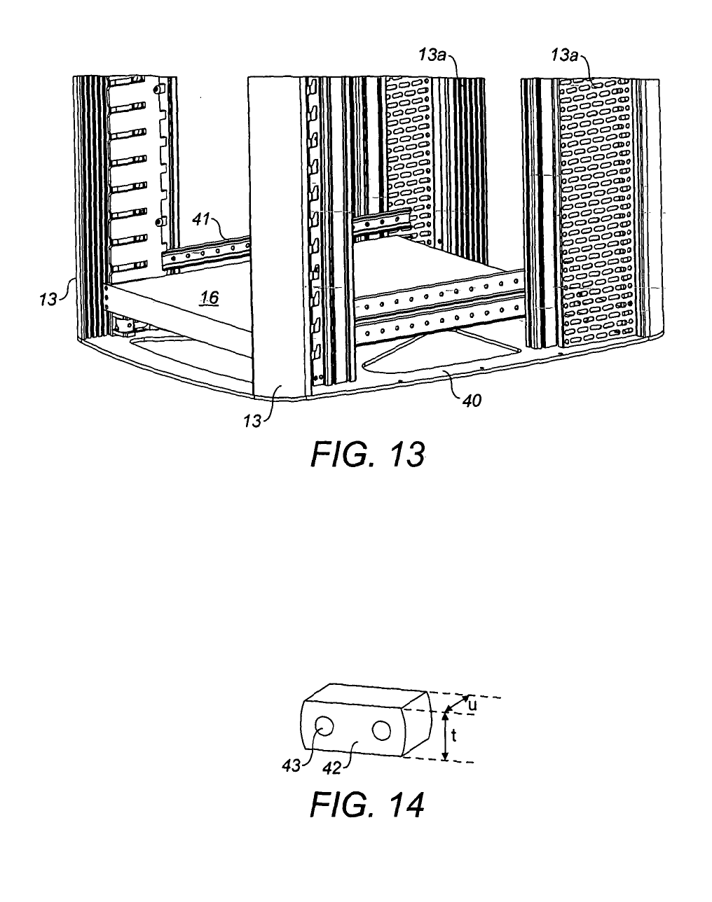

FIG. 13 is a pictorial view of the support structure of FIG. 11 with the item of equipment of FIG. 12 inserted therein;

FIG. 14 is an enlarged view of the guide element; and

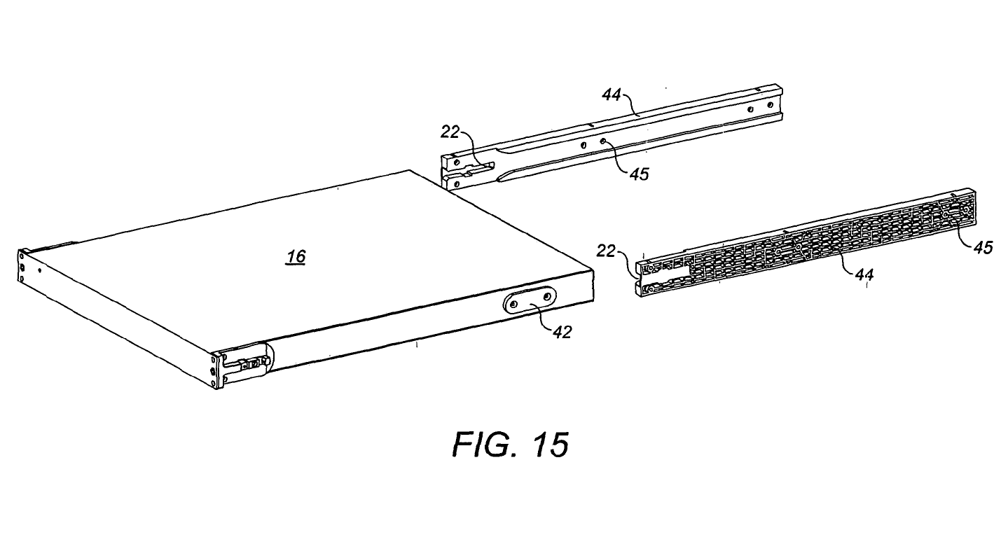

FIG. 15 is a pictorial view of modified guide rails for an alternative embodiment of the invention showing how the isomer equipment is to be supported thereby.

FIGS. 1 and 2 illustrate the mounting of a variety of equipment 16 of different dimensions on a racking system 10 of the present invention. The racking system 10 comprises a support structure 11 (FIG. 3) which is constructed from a plurality of vertical support members 13 (FIG. 4). The number of support members 13 can be varied according to the size of stack required. The minimum number which can be used is two, and there is no limit on the maximum number.

The support members 13 are preferably extruded metal sections incorporating a number of longitudinal channels 17 (as shown in FIG. 5) for receiving fixings. The support members 13 are preferably self supporting with a stabilising member 15 extending horizontally from a lower end of each support member 13. Optionally, a plurality of feet 16 may be attached to the base of the stabilising members 15.

If the racking system 10 is intended to be permanent, the support members 13 may be attached to a wall or other permanent surface rather than free standing.

Each support member 13 is preferably connected to at least one adjacent support member by means of one or more horizontal cross-members 14, preferably at the top and bottom. The support members 13 and cross-members 14 are provided with means for attachment. For example this may comprise apertures located in the support members 13 for receiving spigots 19 located on the ends of the cross member 14 to provide a push fit connection. For additional safety, pins or other locking means 26 may be used to secure the spigots 19 in the apertures.

The cross members 14 enable the pairs of support members 13 to be joined in a manner that allows the distance between the support members 13 to be varied. Cross members 14 of different lengths may be used between adjacent pairs of support members 13. The racking system 10 may include a number of sets of different fixed length cross members 14, or the cross members 14 may be telescopic.

The support members 13 include laterally extending slots, preferably in the form of an elongate slotted panel 21 extending along the length of each support member 13. More preferably, two parallel slotted panels 21 are attached to each support member 13, such that equipment 16 can be attached to each side of the support member 13. Each slotted panel 21 is provided with a series of spaced apart slots 22 that extend laterally (horizontally or at a downward angle) into the panel member 21 along its length to form a comb-like structure. The slotted panels 21 are preferably laser cut from sheet metal.

The racking system 10 further comprises a plurality of individually lockable mounting members 12, which can be fitted either directly to items of equipment or to shelves which are to be mounted in the racking system 10. FIGS. 7 to 10 show one embodiment of mounting member 12. These mounting members 12 comprise a back-plate 30, to which is attached a substantially T-shaped element 31. The stem of the T-shaped element 31 must be of a size and shape so that it can be inserted into the slots 22 in the support members 13. In the stem of the T-shaped element 31 is a recess, notch or groove 32 inside which is mounted a locking element 24. In the cross piece of the T-shaped element 31 is a locking actuator 35 by means of which the locking element 24 is actuated.

In this embodiment of a mounting member 12, the locking element 24 has a substantially rectangular cross section (ideally with rounded ends) with a width (x) which is less than the width (w) of the slots 22 and a length (y) which is greater than the width (w) of the slots 22, but less than the width (z) of the locking apertures 23. The locking actuator 35 causes the locking element 24 to rotate. Where this type of locking element 24 is used each slot 22 of the slotted panel 21 is provided with a wider portion which forms a locking aperture 23, as shown in FIG. 6.

In its unlocked position (FIG. 9) the locking element 24 is oriented so that the narrower width (x) lies between the surfaces of the stem of the T-shaped element 31 which engage with the slot 22. In the locked position (FIG. 10) the longer length (y) extends beyond the surfaces of the stem of the T-shaped element 31 and engages in the locking aperture 23.

The mounting members 12 further comprise suitable means for attachment to the equipment 16 without having to modify the equipment 16. A non-limiting example of such means comprise holes 33 drilled through the cross piece of the T-shaped element that enable it to be screwed onto the equipment 16 as shown in FIG. 8.

The actual shape and configuration of the mounting member 12 can be varied from that illustrated, but it must be capable of being attached to equipment 16, and include a component which is of a size and shape that will slide easily into the slots 22. Similarly the design and configuration of the locking mechanism can be varied, the essential requirement being that it can be activated, to lock the mounting member 12 in a secure stationary position in a slot 22, and deactivated, to enable the mounting member 12 to be removed from the slot 22.

The mounting members 12 can be manufactured from any suitable material. A non-limiting example of a suitable material is polyphthalamide (also known as PPA or high performance polyamide and sold under the trade mark Grivory™. Preferably, the manufacturing process used to form the mounting members 12 is injection moulding. The combination of manufacturing process and material of injection moulded polyphthalamide results in a tough and low cost component with a high durability.

In use, the preferred basic support structure 11 is constructed by connecting a plurality of support members 13 with pairs of cross members 14. The width between each pair of support member 13 is selected according to the width of the equipment 16 to be mounted on the system 10. At least one or more mounting members 12 is fitted to each (usually) vertical side or end of a piece of equipment 16. Each item of equipment 16 is then placed between two support members 13. The desired height is selected by inserting the stem of the T-shaped elements 31 of the respective mounting members 12 into horizontally aligned slots 22 in the opposing slotted panels 21. When the equipment 16 is in its correct position, the back-plate 30 of the mounting member 12 preferably sits flush against the front end of the slotted panel 21 and the stem of the T-shaped element 31 is wholly contained within and supported by the slot 22.

Once an item of equipment 16 to be mounted has been positioned in the racking system 10 as desired, it is locked into place by individually activating the locking elements 24 of each mounting member 12 to move them from the unlocked position to the locked position. The locked mounting members 12 cannot then be moved within the slots 22, thus supporting the item of equipment 16 in a stationary position. The item of equipment 16 can be subsequently removed, by first de-activating the locking elements 24 on each of the mounting members 12 so that they move from the locked position to the unlocked position. This enables individual items of equipment to be replaced, repaired or serviced easily.

Accidental unlocking of the equipment is prevented, since two actions are required to unlock the equipment 16, namely separately unlocking the locking elements 24 on the mounting member 12 on each side of the equipment 16.

The racking system 10 is disassembled by carrying out the assembly process in reverse. The ability to disassemble the vertical support members 13 and the horizontal cross members 14 of the support structure 11 enables the structural components of the racking system 10 to be transported in a space efficient and economically efficient manner.

Most outside broadcasting equipment tends to have a relatively small depth compared to the height and width defining the front face of the equipment. Hence the lengths of the slots 22 and the mounting members 12 can be, say, 4-10 cm long. However equipment used in other applications, such as military, marine or industrial, may have a greater depth measurement. To support this, the lengths of the slots 22 and the mounting members 12 can be significantly extended.

Alternatively, rear support members 13a can be mounted behind the previously described support members 13 using suitable connecting cross members or frames 40. Support rails 41 (preferably having a C-section) are attached between the front and rear sets of support members 13,13a in line with the slots 22 in the slotted panels 21 attached to the front support members 13. Guide elements 42 (see FIG. 14) are attached to the rear ends of each of the vertical side faces of the equipment 16 (as shown in FIG. 12). The guide elements 42 are preferably flat plastic members with means 43 for attaching them to the equipment 11. The guide elements 42 have a depth (u) similar to that of the back plate 30 of the mounting members 12. Thus when attached to the equipment 16, the guide elements 42 do not project sufficiently far from the sides of the equipment 16 to reach the slotted panels 21. The guide elements 42 have a width (t) which fits snugly in the C-section support rails 41 and can slide within the rails 41.

Thus, when the equipment 16 is to be mounted, the rear of the equipment is inserted between a pair of slotted panels 21 and the guide elements 42 located in the support rails 41. The equipment 16 is pushed further rearwardly and the guide elements 42 are supported by and slide along the support rails 41. The T-shaped elements 31 of the mounting members 12 are then pushed into the corresponding slots 22 of the slotted panels 21 at the same height as the support rails 41 and locked-in position when fully inserted.

The mounting members 12 and guide elements 42 described above can be used with an alternative support structure comprising pairs of support rails 44 which can be used for single pieces of equipment 16, or which can be used to replace the slotted panels 22 and support rails 41 described above. Each support rail 44 preferably has a portion which has a C-section profile extending from one end along the majority of its length. This acts in the same way as the support rails 41 described above. At the opposite end of each support rail 44 is a slot, which functions in exactly the same way as the slots 22 in the slotted panels 21. The support rails 44 are preferably injection moulded, but may be made by other suitable methods and may be made from plastics or metal. The support rails 44 are provided with means 45 for attaching them to other items. This is preferably a simple screw or bolt hole. The support rails 44 are provided in pairs and a single pair can be attached to opposing walls, in the same horizontal plane, of items of furniture, flight cases, machinery etc. to receive a single item of equipment 16.

Where multiple items of equipment 16 are required to be supported, a number of pairs of support rails 44 may be mounted one above each other. They may also be mounted between the support members 13 and rear support members 13a described previously, to replace the slotted panels 21 and guide rails 41.

1. A racking system, said system comprising:
a plurality of parallel vertical support members, each provided with a series of slots spaced apart along at least a section of the length of the support member; and
at least one pair of mounting members for direct attachment one on each side of an item of equipment, each mounting member comprising an individually activatable locking element, when the locking element is in an unlocked position, the mounting member is slidable into and out of a slot, and when the locking element is in a locked position the mounting member is restrained from movement within the slot.

2. A racking system as claimed in claim 1, wherein adjacent pairs of support members are joined together by one or more horizontal cross members.

3. A racking system as claimed in claim 2, wherein the one or more horizontal cross members are telescopic.

4. A racking system as claimed in claim 1, further comprising a stabilising member attached to the base of each support member.

5. A racking system as claimed in claim 1, in which each support member has two parallel series of slots.

6. A racking system as claimed in claim 16 further comprising first and rear support members and guide rails mounted in line with each of the slots between a front and rear support member, for receiving and supporting a guide element attached to an item of equipment.

7. A racking system as claimed in claim 6 in which the support rails have a substantially C-section profile.

8. A racking system, said system comprising:
at least one pair of parallel horizontal support members, each comprising a slot at one end of the member and a guide rail at the other end for receiving and supporting a guide element attached to an item of equipment; and
a plurality of mounting members for attachment to an item of equipment, each mounting member comprising an individually activable locking element, when the locking element is in an unlocked position, the mounting member is slidable into and out of a slot, and when the locking element is in a locked position the mounting member is restrained from movement within the slot.

9. A racking system as claimed in claim 8, wherein the locking element is rotatable between a first unlocked position and a second locked position.

10. A racking system as claimed in claim 8, in which locking apertures are provided in the slots for securing the locking elements when in the locked position.

11. A racking system as claimed in claim 8, in which the mounting member further comprise a locking actuator to manually lock and unlock the locking element.

12. A racking system as claimed in claim 8, in which the mounting members further comprise means for attachment to items of equipment.

13. A racking system as claimed in claim 9 wherein the mounting member comprises an elongate rail attached to a back-plate.

14. A racking system as claimed in claim 8, further comprising a plurality of guide elements for attachment to an item of equipment.

15. (canceled)

16. A racking system as claimed in claim 1, further comprising a plurality of support rails for receiving and supporting guide elements attachable to an item of equipment.

17. A mounting member for direct attachment to an item of equipment, said mounting member comprising:
an individually activatable locking element, when the locking element is in an unlocked position, the mounting member is slidable into and out of a slot, and when the locking element is in a locked position the mounting member is restrained from movement within the slot.

18. A mounting member according to claim 17, wherein the locking element is rotatable between a first unlocked position and a second locked position.

19. A kit of parts comprising one or more mounting members according to claim 17 wherein one or more guide elements attachable to an item of equipment.
